(19) United States
(12) Patent Application Publication
(10) Pub. No.: US 2014/0225284 A1
(43) Pub. Date: Aug. 14, 2014

(54) LOW-COST CHIP PACKAGE FOR CHIP STACKS

(71) Applicant: ORACLE INTERNATIONAL CORPORATION, Redwood City, CA (US)

(72) Inventors: Hiren D. Thacker, San Diego, CA (US); Ashok V. Krishnamoorthy, San Diego, CA (US); John E. Cunningham, San Diego, CA (US)

(73) Assignee: Oracle International Corporation, Redwood City, CA (US)

(21) Appl. No.: 13/764,622

(22) Filed: Feb. 11, 2013

(51) Int. Cl. H01L 23/28; H01L 21/82

(52) U.S. Cl. CPC H01L 23/28; H01L 21/82
USPC 257/787; 438/107

(57) ABSTRACT

A chip package is described. This chip package includes a housing having a surface and a cavity, defined by an edge in the surface, with slots arranged at an angle relative to the surface. For example, the angle may be between 0° (in a plane of the surface) and 90° (perpendicular to the plane). Alternatively, the angle may be 0°. Moreover, the slots may be configured to accommodate a set of semiconductor dies arranged in a stack along a direction perpendicular to a plane of the slots, and the semiconductor dies may be offset from each other in a horizontal direction in the plane of slots so that one side of the stack defines a stepped terrace.

### BACKGROUND

1. Field

The present disclosure generally relates to the design of a semiconductor chip package. More specifically, the present disclosure relates to the design of a chip package that facilitates assembly and integration of a group of chips arranged in a stack.

2. Related Art

Chip packages that include stacked semiconductor chips can provide higher performance (such as low latency and high bandwidth) and lower cost in comparison to conventional individually packaged chips that are connected to a printed circuit board. These chip packages also provide certain advantages, such as the ability to: use different processes on different chips in the stack, combine higher density logic and memory, and transfer data using less power. For example, a stack of chips that implements a dynamic random access memory (DRAM) can use a high-metal-layer-count, high-performance logic process in a base chip to implement input/output (I/O) and controller functions, and a set of lower metal-layer-count, DRAM-specialized processed chips can be used for the rest of the stack. In this way the combined set of chips may have better performance and lower cost than: a single chip that includes I/O and controller functions manufactured using the DRAM process; a single chip that includes memory circuits manufactured using a logic process; and/or attempting to use a single process to make both logic and memory physical structures. In addition, a chip package with a stack of chips can allow memory to be placed in close proximity to a processor.

However, it can be challenging to integrate even a single memory chip with a processor. For example, face-to-face integration may be problematic because it may block access to power/ground and the input/output signal lines for the processor. Alternatively, if a memory chip is placed on the backside of the processor, through-silicon vias (TSVs) may be needed in the processor and cooling of the processor may be more difficult. These problems are compounded with a stack of chips because each of these chips may require associated TSVs. In addition, there may be problems associated with power density and the need to supply power to all of the chips in the stack.

Alternatively, a stack of memory chips may be integrated side-by-side with a processor. Researchers have investigated: a vertical stack of chips (which is sometimes referred to as a ‘plank stack’) with and without TSVs; a stack of chips in which the chips are offset from each other, thereby defining a terrace with exposed pads, with a high-bandwidth ramp component (which is positioned approximately parallel to the terrace) electrically coupled to the exposed pads; and a spiral stack with inductive inter-chip interconnects. Each of these proposed approaches poses integration challenges (such as alignment issues), which can reduce the yield and increase the cost of the chip package.

Hence, what is needed is a chip package that offers the advantages of stacked chips without the problems described above.

### SUMMARY

One embodiment of the present disclosure provides a chip package that includes a housing having a surface and a cavity defined by an edge in the surface. This cavity includes slots arranged at an angle relative to the surface. For example, the angle may be between 0° (in a plane of the surface) and 90° (perpendicular to the plane). Alternatively, the angle may be 0°. Moreover, the slots may be configured to accommodate a set of semiconductor dies arranged in a stack along a direction perpendicular to a plane of the slots, and the semiconductor dies may be offset from each other in a horizontal direction in the plane of slots so that one side of the stack defines a stepped terrace.

In some embodiments, the housing is fabricated using injection molding. Therefore, the housing may include: a plastic, glass and/or a plastic impregnated with glass.

Moreover, the slots may be configured to self-align the semiconductor dies in the stack. Alternatively or additionally, the housing may include alignment features configured to mate with corresponding alignment features disposed on the semiconductor dies.

In some embodiments, the surface includes alignment pins disposed on the surface, where the alignment pins are configured to align the housing relative to a substrate. In another example, the surface may include clamps disposed on the surface, wherein the clamps are configured to mechanically couple the housing to the substrate.

In some embodiments, the slots are configured to accommodate semiconductor dies having thicknesses between 10 and 20 μm.

Furthermore, the housing may include a material having a Young's modulus less than a predefined value disposed on surfaces of the slots, and the material may reduce stress in the chip package.

Additionally, the housing may include a material having a thermal conductivity exceeding a predefined value disposed on surfaces of the slots, where the material is configured to conduct heat away from the semiconductor dies.

Another embodiment provides a system that includes the chip package and the set of semiconductor dies arranged in the stack in the direction. For example, the semiconductor dies may be mechanically coupled to the housing by underfill (such as epoxy or glue), and the housing may include channels to guide placement of the underfill in the system.

Another embodiment provides a method for assembling a system. During this method, the set of semiconductor dies are inserted into the slots in the housing in the system, where the housing has the surface and the cavity defined by the edge in the surface. Moreover, the cavity may include the slots arranged at the angle relative to the surface. Furthermore, the set of semiconductor dies may be arranged in the stack along the direction perpendicular to the plane of the slots, and the semiconductor dies may be offset from each other in the horizontal direction in the plane of slots so that one side of the stack defines a stepped terrace. Then, the underfill may be provided in the channels in the housing to mechanically couple the semiconductor dies to the housing, where the channels guide placement of the underfill in the system.

### BRIEF DESCRIPTION OF THE FIGURES

FIG. 1 is a block diagram illustrating a chip package in accordance with an embodiment of the present disclosure.

FIG. 2 is a block diagram illustrating a side view of a system that includes the chip package of FIG. 1 in accordance with an embodiment of the present disclosure.

FIG. 3 is a block diagram illustrating a side view of a system that includes the chip package of FIG. 1 in accordance with an embodiment of the present disclosure.

FIG. 4 is a block diagram illustrating a side view of a system that includes the chip package of FIG. 1 in accordance with an embodiment of the present disclosure.

FIG. 5 is a block diagram illustrating a side view of a system that includes the chip package of FIG. 1 in accordance with an embodiment of the present disclosure.

FIG. 6 is a block diagram illustrating a side view of a system that includes the chip package of FIG. 1 in accordance with an embodiment of the present disclosure.

FIG. 7 is a block diagram illustrating a top view of a system that includes the chip package of FIG. 1 in accordance with an embodiment of the present disclosure.

FIG. 8 is a flow chart illustrating a method for assembling a system in accordance with an embodiment of the present disclosure.

Note that like reference numerals refer to corresponding parts throughout the drawings. Moreover, multiple instances of the same part are designated by a common prefix separated from an instance number by a dash.

### DETAILED DESCRIPTION

Embodiments of a chip package, a system that includes the chip package, and a method for assembling the system are described. This chip package includes a housing having a surface and a cavity, defined by an edge in the surface, with slots arranged at an angle relative to the surface. For example, the angle may be between 0° (in a plane of the surface) and 90° (perpendicular to the plane). Alternatively, the angle may be 0°. Moreover, the slots may be configured to accommodate a set of semiconductor dies arranged in a stack along a direction perpendicular to a plane of the slots, and the semiconductor dies may be offset from each other in a horizontal direction in the plane of slots so that one side of the stack defines a stepped terrace.

In this way, the chip package may facilitate assembly and integration of the stack of semiconductor dies. For example, the chip package may precisely align and house the stack, including passive alignment and assembly techniques. Moreover, the chip package may increase mechanical stability while reducing the risk of mechanical damage, and may facilitate thermal management, thereby allowing stack to be used in close proximity to a processor or another logic chip. Thus, the chip package may be used in high-yield, low-cost systems.

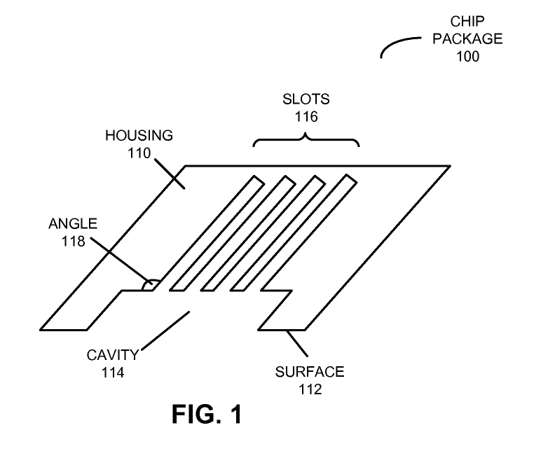

We now describe embodiments of a chip package. FIG. 1 presents a block diagram illustrating a chip package 100. This chip package includes a housing 110 having a surface 112 and a cavity 114 defined by an edge in surface 112. Moreover, cavity 114 includes slots 116 arranged at an angle 118 relative to surface 112. For example, angle 118 may be between 0° (in a plane of surface 112) and 90° (perpendicular to the plane). Alternatively, angle 118 may be 0°.

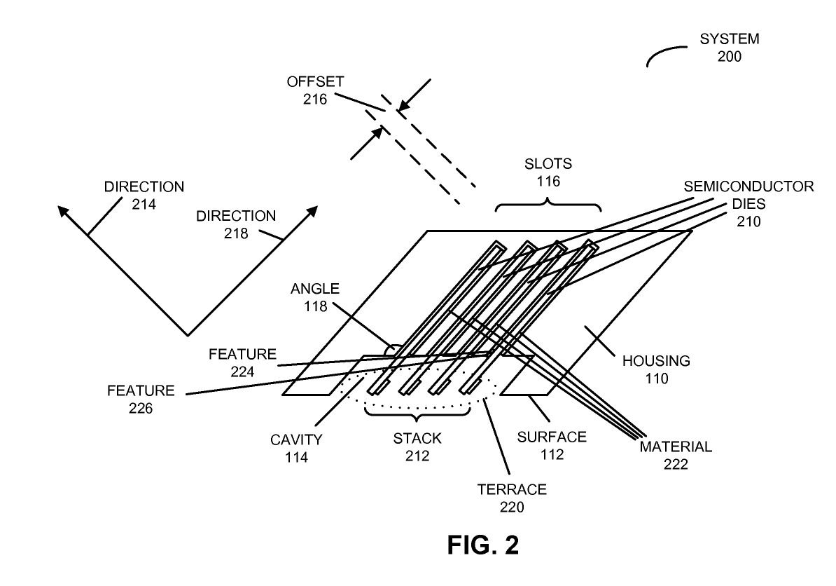

As illustrated in FIG. 2, which presents a block diagram illustrating a side view of system 200 that includes chip package 100 (FIG. 1), slots 116 may accommodate a set of semiconductor dies 210 or chips arranged in a stack 212 (which is sometimes referred to as a ‘ramp stack’) along a direction 214 perpendicular to a plane of slots 116. These semiconductor dies may be offset from each other by an offset 216 in a direction 218 in the plane of slots 116 so that one side of stack 212 defines a stepped terrace 220. In some embodiments, slots 116 accommodate semiconductor dies 210 having thicknesses between 10 and 20 μm, which may not be possible without housing 110.

In order to reduce cost, housing 110 is fabricated using injection molding (and, more generally, using a technique other than machining and etching). Injection molding is a high-volume manufacturing process for producing three-dimensional components, generally using plastic materials (including thermoplastic and thermosetting plastic materials). This manufacturing technique can be used to manufacture precision and small components. In general, the process requires creating a mold, typically from a hard metallic material, and then injecting a molten plastic material at high temperature and pressure into the reusable mold. Once the plastic has cooled, the component can be separated from the mold and the process can be repeated. Note that components with dimensions smaller than 1 mil have been successfully fabricated. Moreover, these injection-molded components can be used to facilitate secure alignment within 1 μm. In addition, the component size can be reduced in a controlled manner by impregnating the plastic with glass as is known in the art. Therefore, housing 110 may include: a plastic, glass and/or a plastic impregnated with glass.

The external shape of housing 110 may vary depending on the mechanical requirements of the chip stack. Moreover, the injection-molded fins (that define slots 116) may not extend the entire width of housing 110. For example, housing 110 may include two pieces or halves (such as left and right) which bind semiconductor dies 210 together from opposite sides so that the fins between semiconductor dies 210 need not extend all the way across. Similarly, the fins may not need to extend the entire length of semiconductor dies 210 (such as top to bottom). This may reduce or prevent the risk of broken fins between semiconductor dies 210. Given that semiconductor dies 210 and the assembly are essentially rigid after being assembled (for example, as discussed below, underfill may be used to hold semiconductor dies 210 in place), the fins may serve to guide and position semiconductor dies 210 during assembly but may not be central to the structural integrity once the stack is in place.

The two halves may be designed to have a gliding mechanism with respect to each other, but with a limited range of motion. In this way, during assembly, the two halves may be pulled apart slightly and semiconductor dies 210 may then be placed against the fins. Note that the separation between the two halves may be limited so that semiconductor dies 210 are supported by fins even at the largest separation between the two halves. Once all semiconductor dies 210 have been placed in their appropriate positions, then the two halves of the injection-molded housing 110 may be brought together. Moreover, one half may have at least one negative feature (such as a pit or a hole) on each end that matches up with positive features (such as a pin) on the two ends of the other half. These positive-negative feature combinations may provide a locking mechanism that is activated when the two halves are brought together. After the two halves are in their locked position, the semiconductor dies 210 in the enclosure may be aligned with each other in one direction.

Furthermore, housing 110 may include a material 222 (such as a polymer or a soft plastic) having a Young's modulus less than a predefined value disposed on surfaces of slots 116, and material 222 may reduce stress in the chip package (such as that associated with components having different lateral dimensions because of process variations). Alternatively or additionally, material 222 may have a thermal conductivity exceeding a predefined value, where material 222 may conduct heat away from semiconductor dies 210. For example, housing 110 may include a heat sink in contact with or in close proximity to semiconductor dies 210. In addition, housing 110 may include vents for heat removal from semiconductor dies 210.

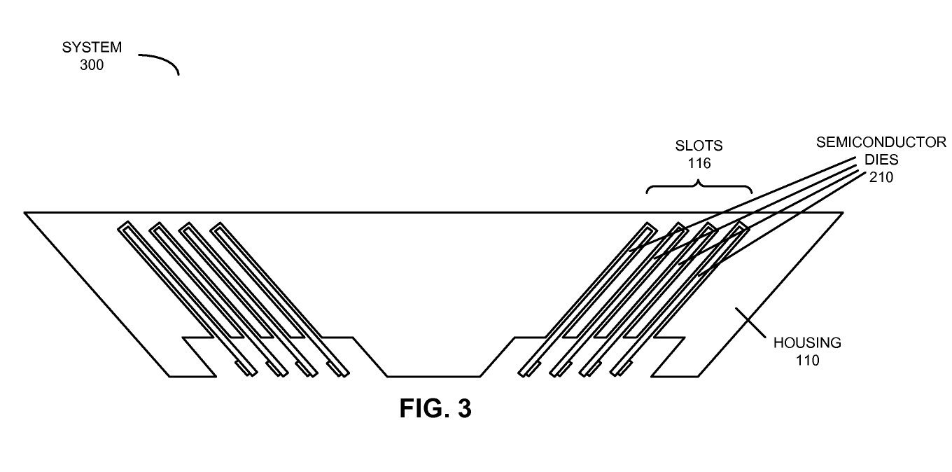

In general, the chip package can accommodate multiple stacks. This is illustrated in FIG. 3, which presents a block diagram illustrating a side view of a system 300 that includes chip package 100 (FIG. 1).

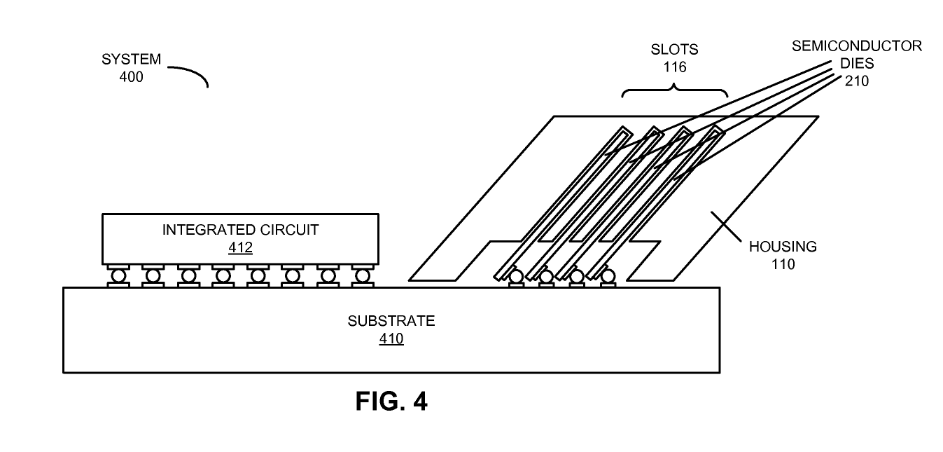

In addition, the chip package may facilitate coupling of the stack(s) to a substrate, such as an integrated circuit or a circuit board (for example, a printed circuit board). This is illustrated in FIG. 4, which presents a block diagram illustrating a side view of a system 400 that includes chip package 100 (FIG. 1) coupled to substrate 410, which in turn is coupled to integrated circuit 412.

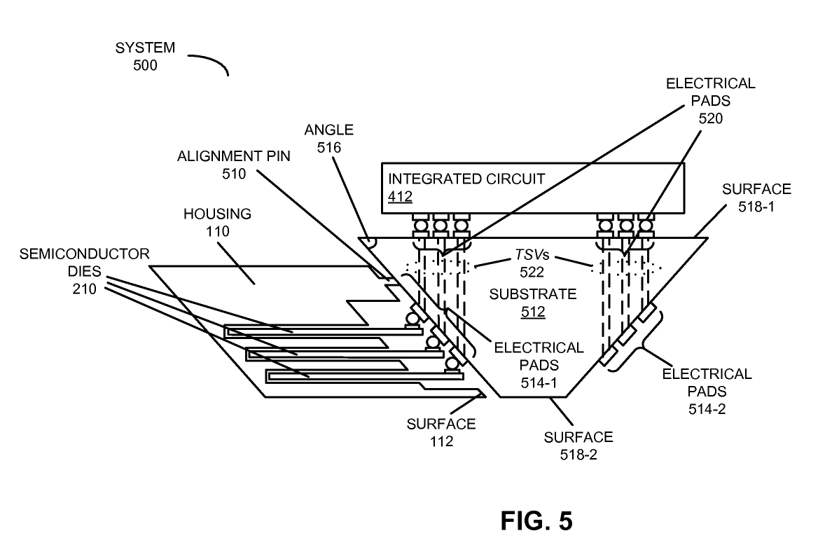

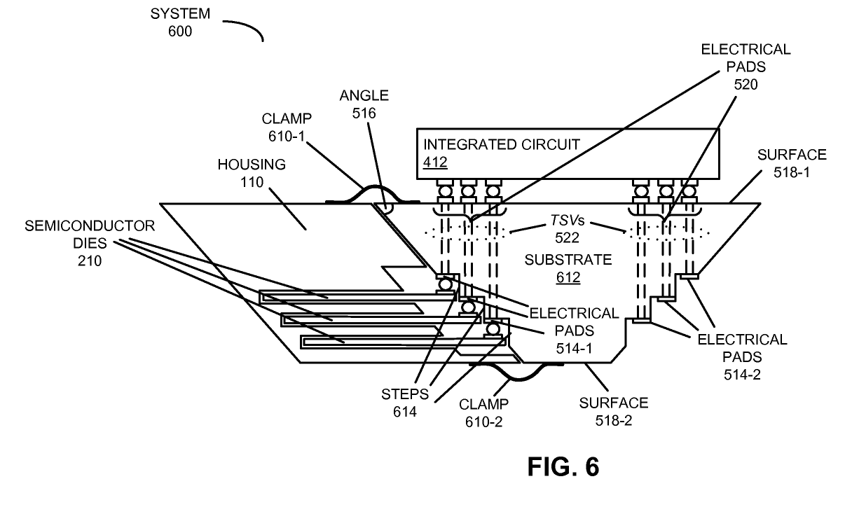

Referring back to FIG. 2, the chip package may include a variety of features to facilitate alignment of components. For example, slots 116 may self-align semiconductor dies 210 in stack 212. In particular, the precision of slots 116 (for example, a precision of ±2-3 μm around the slot width) may hold semiconductor dies 210 by themselves, i.e., the bottom of slots 116 between the fins may constrain movement in and out of housing 110, while the fins themselves constrain the rotation of the semiconductor dies 210. Moreover, semiconductor dies 210 may be mechanically coupled to housing 110 by underfill (on the front and/or backside of housing 110), and housing 110 may include channels to control and guide placement of the underfill at the correct portions and locations in system 200. For example, the underfill may include glue or epoxy. More generally, the underfill may be non-conductive and may be cured under the right temperature or ultraviolet-light conditions. Note that the underfill may be applied after electrical contacts between semiconductor dies 210 and other components (such as substrate 512 in FIG. 5 or substrate 612 in FIG. 6) have been established (e.g., after solder has been reflowed). This approach may prevent alignment changes (such as changes in the chip separation and placement) which can occur as the underfill cures if the underfill were applied to semiconductor dies 210 without housing 110 (i.e., without fixing the positions of semiconductor dies 210 a priori). In addition, the underfill may assist in heat transfer away from semiconductor dies 210. Note that housing 110 also prevents the accumulation of chip misalignment in the stack during the initial assembly or the final curing process, which may be useful given the fixed pitch and the dimensions to which semiconductor dies 210 conform.

However, this approach to integration may involve precise control and uniformity of the dimensions of semiconductor dies 210. As such, a dicing process may need to be controlled with a precision less than 10 μm. In some embodiments, a laser-sawing process may be used to singulate chips. Additionally, a pit-and-thin technique may be used, in which etch pits having a depth less than the chip thickness are etched in the dicing lanes, and then the chip thickness is reduced by thinning the chips from the back surface to singulate them.

Alternatively or additionally, housing 110 may include alignment features (such as feature 224) that mate with corresponding alignment features (such as feature 226) disposed on semiconductor dies 210 (in FIG. 2, only features 224 and 226 are shown for clarity) and/or slots 116 may contain internal features (such as guiding grooves) to support semiconductor dies 210. For example, positive alignment features may be included on housing 110, and negative alignment features may be included on semiconductor dies 210 so that each semiconductor die locks to part of the fin or housing 110 as it is slid into place. Alternatively or additionally, the positive alignment features may be on semiconductor dies 210 and the negative alignment features may be on housing 110. This may eliminate the need for precision singulation of semiconductor dies 210.

As shown in FIG. 5, which presents a block diagram illustrating a side view of a system 500 that includes chip package 100 (FIG. 1), there may also be additional alignment features. In particular, surface 112 may include alignment pins (such as alignment pin 510, which may include a post or semi-spherical dome) disposed on surface 112, where alignment pin 510 aligns housing 110 relative to substrate 512.

Note that substrate 512 (which is sometimes referred to as an ‘interposer’) may have electrical pads 514 (such as electrical pads 514-1) on at least one side (or slanted sidewall edge) that is at an angle 516 relative to surfaces 518 of substrate 512. These electrical pads may be electrically coupled to electrical pads 520 on surface 518-1 of substrate 512 by through-substrate vias (TSVs) 522. Electrical pads 514 may be disposed at different vertical positions on at least the one side. For example, electrical pads 514 may have a pitch along a vertical direction (perpendicular to surface 518-1) of 50-200 μm (which corresponds to a vertical pitch of semiconductor dies 210 in the stack), and a horizontal pitch (into the plane of FIG. 5) of 50-300 μm (which matches the pitch along rows of input/output electrical pads on semiconductor dies 210).

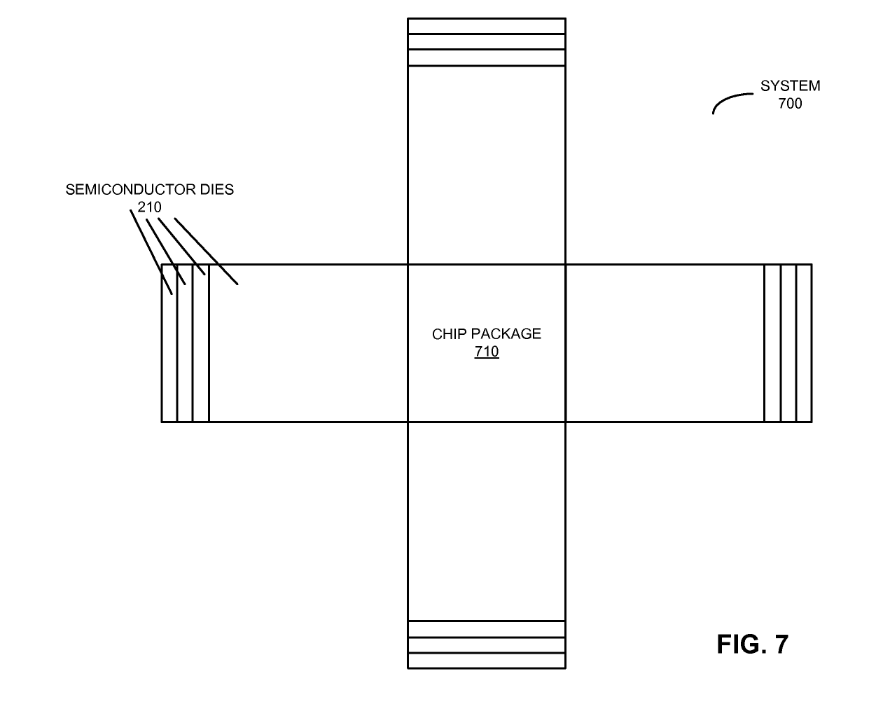

Substrate 512, in conjunction with the chip package, may facilitate mechanical and electrical integration of a high chip-count stack of semiconductor dies. For example, system 500 may align semiconductor dies 210 so that electrical pads on semiconductor dies 210 match positions of electrical pads 514-1, and may provide structural integrity under temperature and humidity variation. Thus, system 500 may facilitate the integration and assembly of a chip stack (such as a high chip-count memory stack) in close proximity to one or more microprocessors, and thus provides low latency and high communication bandwidth between the processor and memory. Therefore, in some embodiments, semiconductor dies 210 provide silicon area that supports logic and/or memory functionality. As described further below with reference to FIG. 7, the chip package is also scalable and can accept several memory chip stacks per processor on a single substrate.

In general, angle 516 is determined by the selected physical interconnect used with electrical pads 514 (for example, C4 solder bumps), the number of semiconductor dies (including their thickness), the target footprint of the stack, and the stress strain limits on the chips stack. In an exemplary embodiment, angle 516 is 15° for 80 semiconductor dies 210 connected using C4 solder bumps (with a pitch of 150-180 μm).

In another example shown in FIG. 6, which presents a block diagram illustrating a side view of a system 600 that includes chip package 100 (FIG. 1), surfaces 518 may include latches or clamps 610 disposed on surfaces 518, wherein clamps 610 mechanically couple housing 110 to substrate 612. (In some embodiments, housing 110 includes alignment pin 510 in FIG. 5 and clamps 610.) Substrate 612 may be micro-machined to have discrete vertical steps 614 corresponding to stepped terrace 220 (FIG. 2), with an array of electrical pads 514-1 (into the plane of FIG. 6) and TSVs 522 at each step.

The number and pitch of TSVs 522 at each of vertical steps 614 may correspond to the pattern of the electrical pads on the corresponding semiconductor dies 210 in the stack. Note that TSVs 522 may be processed to have a metal finish to allow formation of a solder joint with a matching semiconductor die. However, other TSVs and planar redistribution layers on surfaces 518 and/or the sides may be designed and fabricated as needed for distribution of signal, power and ground. In a given chip-package design, the height of each of vertical steps 614 may be the same as the vertical pitch between semiconductor dies 210. Similarly, the horizontal separation between columns of TSVs 522 on substrate 612 may be the same as offset 216 (FIG. 2) of electrical pads on adjacent semiconductor dies 210 in stack 212.

As was the case in the embodiment illustrated in FIG. 5, one column of finished TSVs on one of vertical steps 614 can be attached to a linear array of C4 or copper-pillar bumps on a semiconductor die. Additionally, a stack of semiconductor dies, each of which may have a linear array of solder bumps, may be attached to a two-dimensional array of metal-finished TSV interconnects in electrical pads 514-1.

In some embodiments, housing 110 provides mechanical support to semiconductor dies 210 such that the packaged component is safe from external forces during system assembly or in the field. As shown in FIGS. 5 and 6, housing 110 may contain elements (such as pedestals) that extend beyond the chip stack and are designed to sit on the target package substrate (such as integrated circuit 412 in FIGS. 4-6), an interposer (such as substrate 512 in FIG. 5 or substrate 612 in FIG. 6) or a printed circuit board. Mechanical support may also be provided by stiffer materials embedded into or dissolved in the volume of housing 110 (such as glass) or external pieces that may be attached by chemical or mechanical means to housing 110.

As noted previously, the chip package can accommodate multiple chip stacks. This is illustrated in FIG. 7, which presents a block diagram illustrating a top view of a system 700 that includes chip package 710 with four chip stacks in housings (such as housing 110 in FIG. 1). This assembly may allow each stack (such as each memory stack) to be in close proximity to an integrated circuit (such as integrated circuit 412 in FIGS. 4-6), without needing to be associated with a single integrated circuit. Thus, a given stack may be partitioned so that it can be accessed by memory controllers on different semiconductor dies or, alternatively, an integrated circuit can be interfaced to multiple memory stacks.

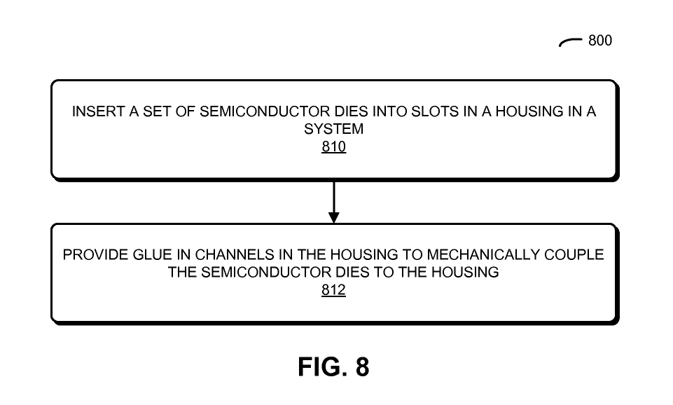

We now describe embodiments of the method. FIG. 8 presents a flow chart illustrating a method 800 for assembling a system that includes chip package 100 (FIG. 1). During this method, the set of semiconductor dies are inserted into the slots in the housing in the system (operation 810), where the housing has the surface and the cavity defined by the edge in the surface. Moreover, the cavity may include the slots arranged at the angle relative to the surface. Furthermore, the set of semiconductor dies may be arranged in the stack along the direction perpendicular to the plane of the slots, and the semiconductor dies may be offset from each other in the horizontal direction in the plane of slots so that one side of the stack defines a stepped terrace. Then, underfill may be provided in the channels in the housing to mechanically couple the semiconductor dies to the housing (operation 812), where the channels guide placement of the underfill in the system.

In some embodiments of method 800 there are additional or fewer operations. Moreover, the order of the operations may be changed, and/or two or more operations may be combined into a single operation.

Components in the preceding embodiments may be coupled in a variety of ways. For example, referring back to FIG. 5, electrical pads 514 may be coupled to semiconductor dies 210 using: solder (such as a reflowable solder layer), microsprings, wire bonds, and/or an anisotropic conducting film. In particular, a given semiconductor die containing a linear array of solder bump pads may be electrically coupled to one column of TSVs 522 on the slanted edge or side of substrate 512. Additionally, semiconductor dies 210 may have a linear array of solder bumps that can be electrically coupled to the two-dimensional array of metal-finished electrical pads 514 along the slanted sides of substrate 512 (i.e., along a vertical direction and into the plane of FIG. 5).

More generally, semiconductor dies 210, substrate 512, and/or integrated circuit (I.C.) 412 may communicate with each other using PxC of electromagnetically coupled signals (which is referred to as ‘electromagnetic proximity communication’), such as capacitively coupled signals and/or proximity communication of optical signals (which are, respectively, referred to as ‘electrical proximity communication’ and ‘optical proximity communication’). In some embodiments, electromagnetic proximity communication includes inductively coupled signals and/or conductively coupled signals.

Therefore, the impedance associated with electrical contacts between semiconductor dies 210, substrate 512, and/or integrated circuit 412 may be conductive (i.e., in-phase) and/or capacitive (i.e., out-of-phase), such as when there is a passivation layer (e.g., a glass layer) above metal pads on or proximate to surfaces of semiconductor dies 210. In general, the impedance may be complex, which includes an in-phase component and an out-of-phase component. Regardless of the electrical contact mechanism (such as microsprings, an anisotropic layer or solder), if the impedance associated with the contacts is conductive, conventional transmit and receive input/output (I/O) circuits may be used in components in the chip package. However, for contacts having a complex (and, possibly, variable) impedance, the transmit and receive I/O circuits may include one or more embodiments described in U.S. patent application Ser. No. 12/425,871, entitled “Receive Circuit for Connectors with Variable Complex Impedance,” by Robert J. Drost et al., Attorney Docket Number SUN09-0285, filed on Apr. 17, 2009, the contents of which are hereby incorporated herein by reference.

Note that microsprings can be fabricated on a wide variety of surfaces, including: a printed circuit board, an organic or ceramic integrated circuit, and/or on the surface of a semiconductor die. Moreover, microsprings can be fabricated with an areal density of inter-chip connections that exceeds the density of input/output signals on high-performance integrated circuits, and the compliance of microsprings can increase the tolerance to mechanical movement and misalignment of components in the chip package.

In some embodiments there may be two or more microspring geometries on a given semiconductor die. For example, data-signal microsprings may be short with blunt ends, while power-signal microsprings may be longer with sharper tips. In addition, by including redundant power-signal microsprings, yield and long-term reliability may be enhanced even if some number of the power-signal microsprings lose their connections.

In order to increase the capacitance of the contacts between the chip package and semiconductor dies 210, in some embodiments a conductive liquid, paste or film may be added to the contact area to fill in any gaps. This would also have the beneficial effect of increasing the area of overlap to the extent that the liquid, paste or film extends beyond the edges of the given microspring.

Microsprings can also provide mechanical and electrical contacts without the use of solder. Thus, the mechanical and/or the electrical coupling between the chip package and semiconductor dies 210 can be removable or remateable (i.e., these components can be remateably coupled), which facilitates rework of system 500 during and/or after assembly and test. Note that remateable mechanical or electrical coupling should be understood to be mechanical or electrical coupling that can be established and broken repeatedly (i.e., two or more times) without requiring rework or heating (such as with solder). In some embodiments, the remateable mechanical or electrical coupling involves male and female components that are designed to couple to each other (such as components that snap together). Thus, remateable components are components that are configured to allow remateable coupling to be established.

However, in some embodiments the mechanical and/or the electrical coupling between the chip package and semiconductor dies 210 is more permanent. For example, it may not be remateable, such as the solder contacts shown in FIG. 5. In these embodiments, electrical pads 514-1 may include under-layer metallization to be compatible with solder-based interconnects.

In the case of an anisotropic film, the anisotropic properties of the anisotropic film enhance electrical conductivity normal to the surface of the anisotropic film while also diminishing electrical conductivity tangential to the surface of the anisotropic film. As a result, the anisotropic film electrically couples mechanically aligned pads on opposite faces of the anisotropic film. For example, the anisotropic film may include the PariPoser® material (from Paricon Technologies, Inc., of Fall River, Mass.). In a PariPoser-type of anisotropic conductive elastomer film, small conductive balls are suspended in a silicone rubber such that the balls generally line up into columns and provide conduction normal, but not tangential, to the surfaces of anisotropic film. As with the microsprings, in general the impedance of the resulting electrical contacts may be conductive and/or capacitive. If the impedance is conductive, conventional transmit and receive I/O circuits may be used in components in the chip package. However, if the impedance is complex, the transmit and receive I/O circuits in the chip package may include one or more embodiments described in U.S. patent application Ser. No. 12/425,871.

While the preceding embodiments illustrate particular configurations of the chip package and the system, a number of techniques and configurations may be used to implement: electrical contact, mechanical alignment, and/or assembly. As described previously, one alignment technique involves the use of etch pits in conjunction with balls in the etch pits to maintain relative alignment of the semiconductor dies 210 and the substrate or integrated circuit 412 (FIGS. 4-6). The ball-and-etch-pit alignment technique can align the surfaces of these components with mechanical tolerances of less than a micron under slight pressure that snaps the surfaces together. Before applying this pressure, pick-and-place machines can be used to achieve mechanical tolerances of less than 10 μm when placing components together. With a little additional time (and resulting assembly cost), these machines can align the components with mechanical tolerances of less than a micron.

For example, a minimal arrangement may use two pits to fix the x-y position of at least the one of the sides of the substrate and semiconductor dies 210 (FIGS. 5 and 6). A mechanical force applied to at least the one of sides and the semiconductor dies 210 would then press the substrate into contact with the semiconductor dies 210. However, thermal distortions and other mechanical forces may prevent a weakly adhesive technique from providing a robust long-term chip-packaging technique. While strong or permanent adhesion of the substrate and the semiconductor dies is robust, it may prevent rework during assembly and test and/or after deployment. In general, packaging techniques that allow some rework are more cost-effective when faced with lower semiconductor-die yields or high expense to test extensively before packaging and assembly. Thus, there may be advantages to packaging techniques that avoid strong adhesives.

More generally, any combination of mechanically coupling (or compatible) positive and negative surface features on the components in the preceding embodiments (such as alignment features 224 and 226 in FIG. 2) may align the components without or in combination with adhesives.

Note that in some embodiments electronic alignment techniques are used to correct for planar mechanical misalignments in the system. For example, electronic alignment may be used with conductive and/or capacitive contacts if a given electrical pad on one surface contacts an array of transmit or receive electrical pads on a facing surface.

In general, functions in the system may be implemented in hardware and/or in software. Thus, the system may include one or more program modules or sets of instructions stored in an optional memory subsystem (such as DRAM or another type of volatile or non-volatile computer-readable memory), which may be executed by an optional processing subsystem. Note that the one or more computer programs may constitute a computer-program mechanism. Furthermore, instructions in the various modules in the optional memory subsystem may be implemented in: a high-level procedural language, an object-oriented programming language, and/or in an assembly or machine language. The programming language may be compiled or interpreted, e.g., configurable or configured, to be executed by the processing subsystem.

Components in the system may be coupled by signal lines, links or buses. These connections may include electrical, optical, or electro-optical communication of signals and/or data. Furthermore, in the preceding embodiments, some components are shown directly connected to one another, while others are shown connected via intermediate components. In each instance, the method of interconnection, or ‘coupling,’ establishes some desired communication between two or more circuit nodes, or terminals. Such coupling may often be accomplished using a number of circuit configurations, as will be understood by those of skill in the art; for example, AC coupling and/or DC coupling may be used.

In some embodiments, functionality in these circuits, components and devices may be implemented in one or more: application-specific integrated circuits (ASICs), field-programmable gate arrays (FPGAs), and/or one or more digital signal processors (DSPs). Furthermore, functionality in the preceding embodiments may be implemented more in hardware and less in software, or less in hardware and more in software, as is known in the art. In general, the system may be at one location or may be distributed over multiple, geographically dispersed locations.

Note that the system may include: a VLSI circuit, a switch, a hub, a bridge, a router, a communication system (such as a WDM communication system), a storage area network, a data center, a network (such as a local area network), and/or a computer system (such as a multiple-core processor computer system). Furthermore, the computer system may include, but is not limited to: a server (such as a multi-socket, multi-rack server), a laptop computer, a communication device or system, a personal computer, a work station, a mainframe computer, a blade, an enterprise computer, a data center, a portable-computing device, a tablet computer, a supercomputer, a network-attached-storage (NAS) system, a storage-area-network (SAN) system, a media player (such as an MP3 player), an appliance, a subnotebook/netbook, a tablet computer, a smartphone, a cellular telephone, a network appliance, a set-top box, a personal digital assistant (PDA), a toy, a controller, a digital signal processor, a game console, a device controller, a computational engine within an appliance, a consumer-electronic device, a portable computing device or a portable electronic device, a personal organizer, and/or another electronic device. Moreover, a given computer system may be at one location or may be distributed over multiple, geographically dispersed locations.

Furthermore, the embodiments of the chip package and/or the system may include fewer components or additional components. Although these embodiments are illustrated as having a number of discrete items, the chip package and the system are intended to be functional descriptions of the various features that may be present rather than structural schematics of the embodiments described herein. Consequently, in these embodiments two or more components may be combined into a single component, and/or a position of one or more components may be changed. In addition, functionality in the preceding embodiments of the chip package and/or the system may be implemented more in hardware and less in software, or less in hardware and more in software, as is known in the art.

While the preceding embodiments use semiconductor dies (such as silicon) in the system, in other embodiments a different material than a semiconductor may be used as the substrate material in one or more of these chips.

Note that components in the preceding embodiments may be fabricated using an additive or positive process (i.e., a material-deposition process) and/or a subtractive or negative process (i.e., a material-removal process). For example, the process may include: sputtering, plating, isotropic etching, anisotropic etching, a photolithographic technique and/or a direct-write technique. Additionally, these processes may utilize a wide variety of materials, including: a semiconductor, metal, glass, sapphire, an organic material, a ceramic material, a plastic and/or silicon dioxide.

In the preceding description, we refer to ‘some embodiments.’ Note that ‘some embodiments’ describes a subset of all of the possible embodiments, but does not always specify the same subset of embodiments.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

1. A chip package, comprising:
a housing having a surface and a cavity defined by an edge in the surface, wherein the cavity includes slots arranged at an angle relative to the surface;
wherein the slots are configured to accommodate a set of semiconductor dies arranged in a stack along a direction perpendicular to a plane of the slots; and
wherein the semiconductor dies are offset from each other in a horizontal direction in the plane of slots so that one side of the stack defines a stepped terrace.

2. The chip package of claim 1, wherein the housing is fabricated using injection molding.

3. The chip package of claim 1, wherein the housing includes a material selected from the group consisting of: a plastic, glass and a plastic impregnated with glass.

4. The chip package of claim 1, wherein the angle is between that of a direction parallel to a plane of the surface and a direction perpendicular to the plane.

5. The chip package of claim 1, wherein the angle is corresponds to a direction in a plane of the surface.

6. The chip package of claim 1, wherein the slots are configured to self-align the semiconductor dies in the stack.

7. The chip package of claim 1, wherein the slots are configured to accommodate semiconductor dies having thicknesses between 10 and 20 μm.

8. The chip package of claim 1, wherein the housing further includes a material having a Young's modulus less than a predefined value disposed on surfaces of the slots; and
wherein the material is configured to reduce stress in the chip package.

9. The chip package of claim 1, wherein the housing further includes alignment features configured to mate with corresponding alignment features disposed on the semiconductor dies.

10. The chip package of claim 1, wherein the housing includes a material having a thermal conductivity exceeding a predefined value disposed on surfaces of the slots; and
wherein the material is configured to conduct heat away from the semiconductor dies.

11-12. (canceled)

13. A system, comprising:
a housing having a surface and a cavity defined by an edge in the surface, wherein the cavity includes slots arranged at an angle relative to the surface; and
a set of semiconductor dies disposed in the slots, wherein the set of semiconductor dies are arranged in a stack along a direction perpendicular to a plane of the slots; and
wherein the semiconductor dies are offset from each other in a horizontal direction in the plane of slots so that one side of the stack defines a stepped terrace.

14. The system of claim 13, wherein the housing is fabricated using injection molding.

15. The system of claim 13, wherein the angle is between that of a direction parallel to a plane of the surface and a direction perpendicular to the plane.

16. The system of claim 13, wherein the angle corresponds to a direction in a plane of the surface.

17. The system of claim 13, wherein the slots are configured to self-align the semiconductor dies in the stack.

18. The system of claim 13, wherein the semiconductor dies are mechanically coupled to the housing by underfill; and
wherein the housing further includes channels to guide placement of the underfill in the system.

19. The system of claim 13, wherein the housing further includes alignment features configured to mate with corresponding alignment features disposed on the semiconductor dies.

20. (canceled)
